(19) United States
(12) Patent Application Publication
(10) Pub. No.: US 2026/0353582 A1
(43) Pub. Date: Nov. 5, 2026

(54) INTEGRATED SERVER EAR CRANE ATTACHMENT POINT

(71) Applicant: HEWLETT PACKARD ENTERPRISE DEVELOPMENT LP, Spring, TX (US)

(72) Inventors: Pin-Che Tsai, Houston, TX (US); Earl W. Moore, Tomball, TX (US); Leroy C. Okoro, The Woodlands, TX (US)

(21) Appl. No.: 19/196,947

(22) Filed: May 2, 2025

(51) Int. Cl. H05K 7/14; H05K 5/02; H05K 7/20

(52) U.S. Cl. CPC H05K 7/1415; H05K 5/0221; H05K 5/023; H05K 7/1489; H05K 7/20236; H05K 7/20763

(57) ABSTRACT

An information system includes a system board having electronic components and a chassis supporting the system board. The chassis includes a top wall having a top ear support and a base having a bottom ear support. The system further includes a server ear, with the server ear including a server ear housing coupled to the chassis at the top ear support and the bottom ear support and a lever. The lever includes a base pivotably coupled to the server ear housing a lever handle extending from the base and including a crane attachment point and movable between an open state and a closed state. The crane attachment point is configured to engage a crane attachment device of a crane of an immersion cooling system to attach the information processing system to the crane.

Information processing systems, (e.g., servers) generate heat during operation and, if the heat is not dissipated or cooling is not provided, damage can occur to various components within the system. One way to provide cooling to a system is through the use of airflow through the system, such as by using fans disposed within the system, with airflow over components providing cooling. Another way to provide cooling to a system is through the use of liquid cooling, where coolant liquids flowing over components remove heat from the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including an integrated server ear crane attachment point.

FIG. 2 is a perspective view of a server ear having an integrated crane attachment point.

FIG. 3 is a perspective view of the server ear of FIG. 2 in an assembled state.

FIG. 4 is a front view of the server ear of FIG. 3.

FIG. 5 is a perspective view of an information processing system in cutaway and including two integrated server ear crane attachment points.

FIG. 6 is a perspective view of an information processing system in cutaway and including an integrated server ear crane attachment point.

FIG. 7 is a rear perspective view of the information processing system of FIG. 6.

FIG. 8 is a side elevation view of the information processing system of FIG. 6.

FIG. 9 is a front perspective view of the information processing system of FIG. 6.

FIG. 10 is a bottom perspective view of the information processing system of FIG. 6.

FIG. 11 is a perspective view of an information processing system including a set of integrated server ear crane attachment points.

FIG. 12 is a perspective view of an information processing system in cutaway and including another example of an integrated server ear crane attachment point.

FIG. 13 is a side elevation view of the information processing system of FIG. 12.

FIG. 14 a perspective view of an information processing system in cutaway and including a set of integrated server ear crane attachment points.

### DETAILED DESCRIPTION

Information processing components, such as CPUs, are increasing in power and heat generation, which is making it increasingly difficult to efficiently cool the system via airflow. As heat generation increases, greater volumes of air must be moved through the system to achieve the same level of cooling. The increase in air volume through the system results in increased power consumption and increased noise. In addition, as the amount of air to be moved through the system increases, costs for the various components, such as fans and heat sinks, also increase.

One alternative method for cooling an information processing system is liquid cooling, in which liquid coolant is used to remove heat from the system. One form of liquid cooling is direct liquid cooling (DLC), in which liquid coolant flows through a system using tubes/pipes, and heat is extracted from heat generating components of the system into the liquid coolant via cold plates coupled to the components. DLC is often used in information processing systems having high component density, such as supercomputers or high-performance computing systems, where there are multiple components generating high amounts of heat. DLC is highly efficient at removing heat from a system, however, DLC has a high cost due to the addition of further components, such as cold plates and coolant pipes, to the system. Due to the complexity of many DLC cooled systems, these additional components are often customized for each particular system, meaning that many components cannot be easily reused.

Immersion cooling, on the other hand, involves submerging part or all of an information processing system in a tank of an electrically non-conductive liquid coolant, such as a dielectric liquid. This allows the liquid coolant to contact some or all of the information processing components, such that heat generated by the components can be discharged into the coolant. The heated coolant can then be circulated through a heat exchanger to remove the heat before being recirculated into the tank. Immersion cooling represents an efficient method of cooling a system without a corresponding increase in power or noise output, as may occur in an air-cooled system. Similarly, immersion cooling allows some of the benefits of direct liquid cooling, namely, the increase in heat able to be removed from the system without requiring a custom designed cooling system based on the particular information processing system. As such, the increase in accessibility and affordability of immersion cooling systems make immersion cooling an attractive option for system cooling.

In immersion cooling systems, because the information processing system is at least partially submerged in a tank, the information processing system is configured to be selectively lifted and/or lowered into the tank. Due to the size of information processing systems, immersion cooling systems often include an overhead crane system configured to be attached to an information processing system to facilitate the lifting and lowering of the information processing system into and out of the tank. More particularly, a crane may be used for safety when lifting the information processing system out of the tank due to the combined weight of the information processing system and the liquid coolant within the information processing system (the liquid will slowly drain out, but this takes time and a significant amount of liquid will be present in the system as it is lifted, thus increasing the overall weight).

To lift an information processing system, a crane's attachment device (e.g., a crane hook) is attached, either directly or indirectly, to a feature on the information processing system which can support the weight of the information processing system and any liquid coolant within the information processing system. However, many information processing systems do not have features, referred to herein as crane attachment points, which are simultaneously compatible with receiving the crane's attachment device, accessible when the information processing system is immersed, and capable of supporting the weight of the information processing system. In particular, information processing systems that were originally designed for air cooling often do not include crane attachment points. Thus, when an information processing system is being converted from an air cooling configuration to an immersion cooling configuration, there may not be a dedicated crane attachment point to which the overhead crane system can attach, resulting in ad-hoc solutions being implemented.

One means by which a previously air-cooled information processing system may be adapted to allow attachment with a crane attachment device is by engaging components such as cables with existing features of the information processing system. For example, many information processing systems are configured to be mounted on racks and as such, include server ears that protrude laterally from a front of the information processing system to engage with vertical posts of a rack and thereby mount the information processing system to the rack. These server ears may be leveraged to provide attachment points for cables, particularly steel braided cables, which may be wrapped and looped around a server ear to create a crane attachment point. However, the cables may slip, loosen, or otherwise dislodge. This may result in damage to the information processing system, particularly if such slipping occurs during lifting. Furthermore, the cables may have an unprofessional appearance, and because they are ad hoc additions not integrated into the system they may interfere with other aspects of the system, such as by preventing the server from sitting flush on a support system inside the immersion tank.

To address these and other issues, examples disclosed herein relate to integrated server ear crane attachment points which can be installed in an information processing system. More particularly, the crane attachment points may be integrated into a server ear that is included as part of an information processing system, allowing an attachment device of an overhead crane system to be selectively coupled to the information processing system such that the crane can lift or lower the information processing system into or out of an immersion cooling tank containing liquid coolant.

Each integrated crane lifting point may comprise a server ear housing and a lever pivotably attached to the server ear housing. The server ear housing is coupled to the system's chassis, for example via portions of a top wall and a base of the chassis that protrude out over and under the server ear, respectively. The server ear housing may be coupled to the chassis using screws, pins, welding, or any other joining/ fastening technique capable of supporting the weight of the system, including any liquid coolant within the system. The lever may include a lever handle extending from a pivot point and a crane attachment point formed as part of the lever handle. In some examples, the crane attachment point includes an opening formed through the lever handle, with the opening configured to receive an attachment device of an overhead crane. In some examples, this opening has a central axis perpendicular to a pivot axis of the lever. In other examples, this opening has a central axis parallel to the pivot axis. In some examples, the lever handle includes an arm extending between the pivot point and a grasping tab, and the opening is formed through the arm. In other examples, the lever handle may include an arm extending between the pivot point and a grasping tab, and a bracket coupled to and protruding from the arm, with the opening formed through the bracket. In some examples, the lever may be rotatably coupled to the server ear housing by alignment of the at least one lever pivot hole and the at least one server ear housing pivot hole to allow a pivot pin to be passed through the pivot holes. The pivot pin may allow the lever to rotate with respect to the server ear housing between a closed state and an open state. In the closed state, the lever may be at least partially received within a receptacle in the server ear housing such that the crane attachment point on the lever handle is not accessible to receive a crane attachment device. In the open state, however, the lever may be moved at least partially out of the receptacle to allow access to the crane attachment point such that a crane attachment device can be attached to the information processing system. Rotation of the lever to allow the lever to be at least partially received within the receptacle in the server ear may provide space saving when the information processing system is not being actively lifted or lowered (i.e., when the information processing system is immersed in an immersion tank). In addition, rotating the lever to the closed state may assist in preventing inadvertent damage from, e.g., collisions, to the crane attachment point on the lever, prolonging the longevity of the crane attachment point.

In some examples, the lever may be moved to the open state by engaging a grasping tab on the lever handle to apply a force on the lever handle, allowing the lever to rotate about the pivot pin from the closed state to the open state. In some examples, the server ear includes a latch configured to engage the lever to aid the lever in staying in the open state or the closed state. The latch may assist in preventing inadvertent opening or closing of the lever due to, e.g., gravity; however, the force provide by the latch may be overcome by the application of manual force by a user, allowing the lever to move with relative ease both when a user wishes to access the crane attachment point and when the crane attachment point does not need to be accessed.

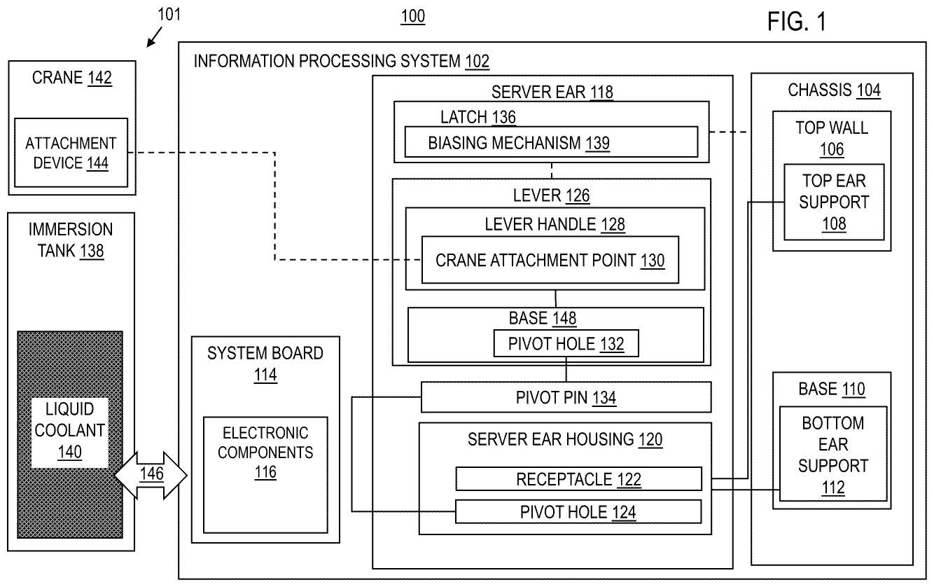

These and other examples are described herein with respect to FIGS. 1-14.

FIG. 1 illustrates an example system 100 including an immersion cooling subsystem 101 and an information processing device 102 with an integrated server ear 118 having a crane attachment point 130. FIG. 1 is schematic in nature, and it should be understood that FIG. 1 is not intended to illustrate specific shapes, dimensions, positional relationships, or other structural details accurately or to scale, unless otherwise noted herein. Implementations of system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Intermittent relationships (e.g., selective coupling) are indicated conceptually by dashed lines extending between the components. Certain positional relationships are indicated by thick, white-filled arrows.

System 100 is a system for operating and immersion cooling information processing devices, such as servers, networking devices, or the like. System 100 includes an information processing system 102 and an immersion cooling subsystem 101. Immersion cooling subsystem 101 includes an immersion tank 138. The immersion tank 138 contains a pool of liquid coolant 140 and is configured to receive multiple information processing systems, including information processing system 102, immersed in that coolant 140 to provide immersion cooling thereto, as will be explained in greater detail below.

Information processing system 102 may be a server, a networking device (e.g., switch, router, etc.), or other device with information processing components. Information processing system 102 may include a chassis 104, a system board 114, and a server ear 118.

Chassis 104 may include structural components to support and/or house other components of system 102. The chassis 104 may, for example, include a housing or enclosure comprising a top wall 106 including a top ear support 108 and a base 110 including a bottom ear support 112. Additional components, such as side walls or a cover may couple together with the top wall 106 and/or the base 110 to define an interior volume in which other components of the system are housed. The chassis may also include other support structures, which may be disposed in or form integral parts of the aforementioned housing, such as drive cages, power supply unit cages, etc. In lieu of forming a housing, chassis 104 may alternatively include a tray or other support structure which supports, but does not necessarily fully enclose, the components of the system.

A system board 114 may be supported by chassis 104. System board 114 may be a motherboard that includes electronic components 116 coupled thereto. Electronic components 116 may include at least some information processing components, such as a central processing unit (CPU), a memory, or the like, as well as other passive or active electrical components (not illustrated), but examples are not so limited, and any system board may be used.

A server ear 118 may be coupled to chassis 104 at the top ear support 108 and the bottom ear support 112. The server ear 118 may include a server ear housing 120, a lever 126, and a latch 136. The server ear housing 120 may be the portion of server ear 118 that couples with the chassis 104 at the top ear support 108 and the bottom ear support 112. When server ear 118 is coupled to chassis 104, the server ear housing 120 may be bounded by the top ear support 108 and the bottom ear support 112.

Server ear housing 120 may define a receptacle 122. More particularly, receptacle 122 may be defined in an interior portion of the server ear housing 120. The receptacle 122 may extend through at least a portion of server ear housing 120 such that a portion of lever 126 is able to be received and held within receptacle 122, as will be explained in further detail below. Server ear housing 120 may further include at least one pivot hole 124 extending through the server ear housing 120, with the pivot hole 124 configured to receive a pivot pin 134, as explained further herein.

Lever 126 may further comprise a lever handle 128 coupled to a base 148. The base 148 of lever 126 may be pivotably coupled to server ear housing 120 via pivot pin 134. More particularly, base 148 of lever 126 may include at least one pivot hole 132. Pivot hole 132 may be aligned with pivot hole 124 in server ear housing 120 such that pivot pin 134 can be passed through pivot hole 124 and pivot hole 132 to allow lever 126 to rotate with respect to server ear housing 120. That is, base 148 of lever 126 may be coupled to server ear housing 120 so as to allow lever 126 to rotate about the pivot pin 134. As such, lever 126 may be movable between an open state and a closed state. Examples are not so limited, however, and lever 126 may be coupled to server ear housing using, e.g., a sliding attachment.

The lever handle 128 may be coupled to base 148 and extend outwardly therefrom, such that lever handle 128 moves when base 148 rotates about pivot pin 134. Lever handle 128 may include a crane attachment point 130 configured to allow coupling of a crane attachment device 144, such as a hook, as will be described further herein. In some examples, crane attachment point 130 comprises an opening through lever handle configured to receive the crane attachment device 144. This opening may have an axis extending perpendicular to the pivot axis in some examples and parallel to the pivot axis in other examples. In some examples, the lever handle 128 comprises an arm (not illustrated) extending between the base 148 and a grasping tab (not illustrated). In some of these examples, the opening of the crane attachment point 130 extends through the arm with an axis perpendicular to the pivot axis. In other examples, the lever handle 128 includes a bracket coupled to and protruding from the arm, with the opening of the crane attachment point 130 extending through the bracket parallel to the pivot axis.

The lever handle 128 may be movable between an open state, in which the crane attachment point 130 is accessible for engagement, and a closed state, in which the crane attachment point 130 is inaccessible for engagement. In the closed state, the lever handle 128 may rest against the server ear housing 120 such that the crane attachment point 130 may be at least partially received within receptacle 122. This may prevent engagement of crane attachment device 144 with the crane attachment point 130. By contrast, in an open state, lever handle 128 may be pivoted with respect to server ear housing 120 such that the crane attachment point 130 disengages with receptacle 122 and is accessible for engagement of the crane attachment device 144. Pivoting of the lever handle 128 may occur when a downward force is applied to the lever handle 128, allowing the lever handle 128 to pivot about pivot pin 134. In some examples, lever handle 128 may include a grasping tab or handle to assist a user in applying a force to the lever handle 128; however, examples are not so limited.

The server ear 118 may further include a latch 136. Latch 136 may be configured to engage with a rail kit (not shown) coupled to chassis 104 and with lever 126. More particularly, one end of latch 136 may engage with the base 148 of lever 126 to provide resistance that aids in maintaining the lever handle 128 in either the open state or the closed state. In addition, in the closed state, a second end of the latch 136 may engage with the rail kit coupled to the chassis 104 to further assist in retaining the lever handle 128 in the closed state. The resistance provided by latch 126 may assist in preventing inadvertent opening or closing due to gravity or unintentional movement yet may allow the latch handle 128 to be manually actuated without first disengaging the latch 136. In addition, the resistance provided on the base 148 of lever 126 by latch 136 may provide additional stability when the information processing system 102 is being lifted and/or lowered. In some examples, the latch 136 may include a biasing mechanism 139, which may aid the latch 136 in keeping the lever 226 in the open or closed state, as described in greater detail herein.

As described above, lever 126 is pivotable between a closed state, in which the crane attachment point 130 is inaccessible, and an open state, in which the crane attachment point is accessible. When lever 126 is in the open state, a crane attachment device 144 couple to a crane 142 may be coupled to the crane attachment point 130 such that information processing system 102 is coupled to crane 142. Information processing system 102 is then able to be moved with respect to immersion tank 138, as shown by arrow 146. More particularly, information processing system 102 may be lowered into immersion tank 138 such that at least some of information processing system 102 is received within liquid coolant 140 held within the immersion tank 138. Alternately, on a condition where information processing system 102 was previously immersed within the liquid coolant 140, crane 142 may lift the information processing system 102 out of the liquid coolant 140 and/or fully out of immersion tank 138. Once the information processing system 102 has been moved with respect to immersion tank 138 by crane 142 (i.e., has been lifted from or lowered into the liquid coolant 140), crane attachment device 144 may be disengaged from crane attachment point 130 and lever 126 may be moved to the closed state, allowing crane attachment point 130 to be received within receptacle 122 of server ear housing 120.

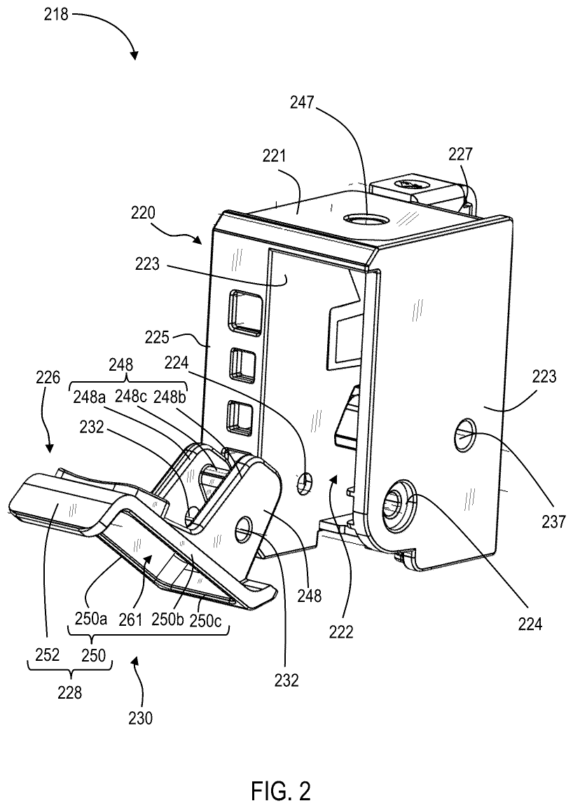

Turning to FIGS. 2-11, an example server ear 218 and an example information processing system 202 which comprises the server ear 218 will be described. Server ear 218 may be one implementation of an example server ear 118, shown in and described with respect to FIG. 1, and may be used in a system such as system 100, described with respect to FIG. 1. System 202 is one example of such a system 100. Some aspects of server ear 218 are best visible in figures also showing system 202, and thus server ear 218 and system 202 will be described together below, but it should be understood that server ear 218 could be used in other systems. Server ear 218 thus comprises components which correspond to (i.e., are implementation examples of) components of the server ear 118, and the correspondence between such components is indicated herein by the components having references numbers with the same last two digits, such as 120 and 220. Aspects of the server ear 118 and its components described above may also be applicable to the server ear 218 and its corresponding components, but the server ear 118 and its components are not limited to the server ear 218 and its components, which are just one example of how the server ear 118 may be implemented. In some instances, aspects of the server ear 118 already described above, which are also applicable to the server ear 218, are not described below to avoid duplicative description.

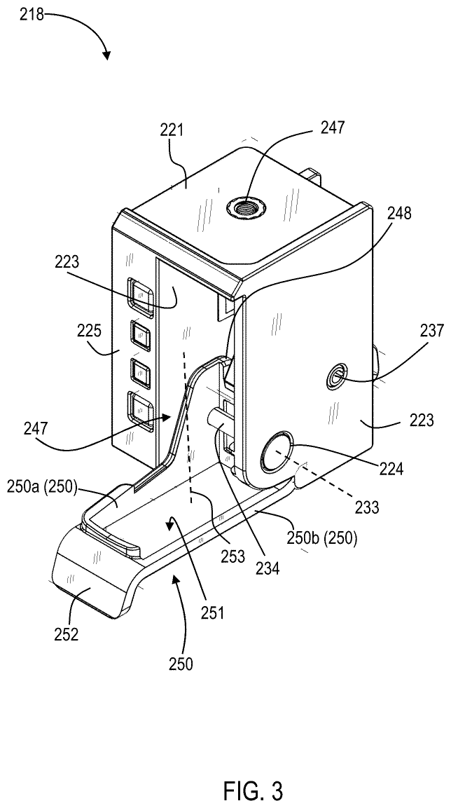

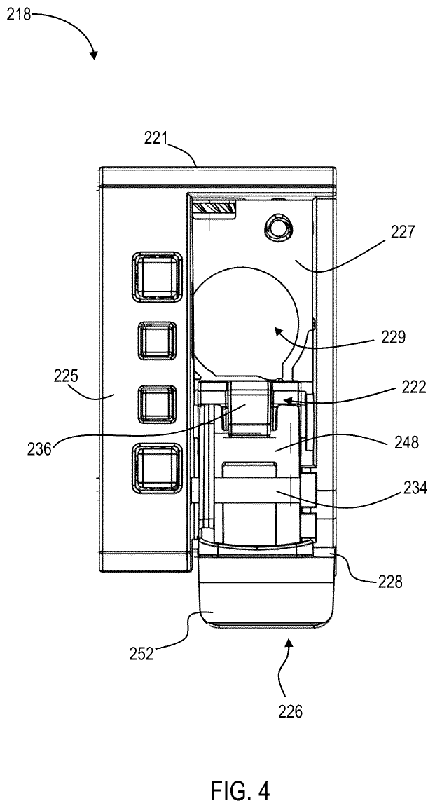

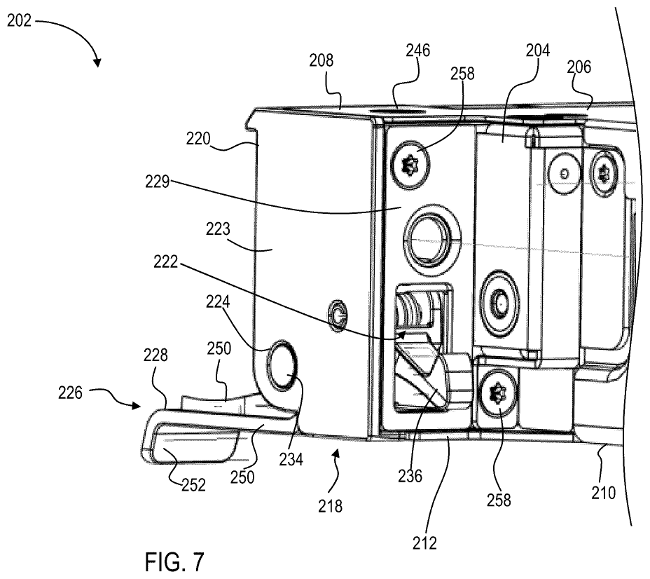

Server ear 218 comprises a server ear housing 220 and a lever 226, with lever 226 coupled to server ear housing 220, as shown particularly in FIGS. 3-4. Server ear housing 220 comprises a top wall 221, a bottom wall disposed opposite top wall 221 (not shown in FIGS. 2-4), and a pair of side walls 223 extending between and coupling top wall 221 to the bottom wall. The top wall 221, side walls 223, and bottom wall define a receptacle 222 of the server ear housing 220. Server ear housing 220 further includes a rear wall 227, as shown in FIG. 4. Rear wall 227 includes an opening 229 formed therethrough, which may be configured to receive additional components when the server ear 218 is coupled to an information processing system. In addition, rear wall 227 may not extend along a full length of the receptacle 222 but may instead leave a portion of receptacle 222 open, as discussed further below with respect to FIG. 7 in particular.

Each side wall 223 includes a pivot hole 224 formed through the side wall 223. The pivot holes 224 are disposed opposite to one another such that pivot holes 224 can receive a pivot pin 234, as discussed further herein. Side wall 223 further includes at least one latch hole 237 configured to allow engagement of a latch, as discussed further herein.

The top wall 221 includes an aperture 247 formed therein, with aperture 247 configured to receive a fastener when system ear 218 is coupled to a chassis, as described further herein. Aperture 247 can be threaded, as shown in FIG. 3, however, examples are not so limited. Additionally, while one aperture 247 is shown in FIGS. 2-3, examples are not so limited and more apertures may be formed within top wall 221.

Lever 226 comprises a lever handle 228 coupled to a base 248. Lever handle 228 comprises an arm 250 coupled to and extending from base 248 and a grasping tab 252 coupled to a distal end of the arm 250 opposite base 248. The arm 250 has an opening 251 formed therethrough. The arm 250 comprises arm portions 250a-250c, which partially surround the opening 251. The arm portions 250a-250c together with grasping tab 252 define the opening 251. The opening 251 and the portions of the lever handle 228 which surround it together form a crane attachment point 230 formed in the lever handle 228. In this example, an axis 253 of the opening 251 is perpendicular to a pivot axis 233, as shown in FIG. 3.

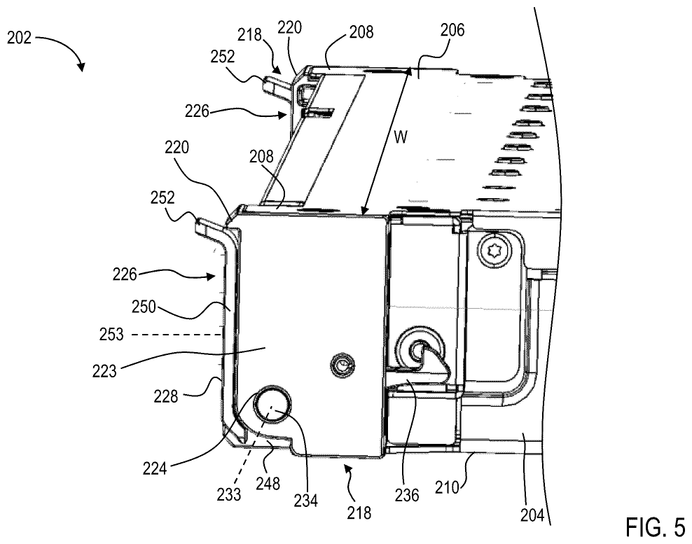

The base 248 comprises two side portions 248a and 248b and connecting portion 248c extending between the side portions 248a and 248b. The side portions 248a and 248b may be connected to the arm portions 250a and 250b, respectively. The side portions 248a and 248b each include a pivot hole 232 formed therethrough. As shown in FIG. 2, arm pivot holes 232 are disposed opposite one another such that a pivot pin 234 can extend through the pivot holes 232. More particularly, to couple lever 226 to server ear housing 220, arm pivot holes 232 and server ear pivot holes 224 are aligned with one another, with lever 226 being inserted into receptacle 222 such that arm pivot holes 232 are adjacent to the interior portion of side walls 223. A pivot pin 234 is then passed through server ear pivot holes 224 and arm pivot holes 232 such that lever 226 is pivotably coupled to the server ear housing 220, as shown in FIG. 3. Once in the assembled state, as shown in FIGS. 3-4, the server ear 218 is able to be installed in an information processing system, as shown in FIGS. 5-11.

Turning specifically to FIGS. 5-11, an example information processing system 202 that utilizes the server ear 218 will be described. Information processing system 202 may be one implementation of an example information processing system 102, shown in and described with respect to FIG. 1, and may be used in a system such as system 100, described with respect to FIG. 1. Information processing system 202 thus comprises components which correspond to (i.e., are implementation examples of) components of the information processing system 102, and the correspondence between such components is indicated herein by the components having references numbers with the same last two digits, such as 120 and 220. Aspects of the information processing system 102 and its components described above may also be applicable to the information processing system 202 and its corresponding components, but the information processing system 102 and its components are not limited to the information processing system 202 and its components, which are just one example of how the information processing system 102 may be implemented. In some instances, aspects of the information processing system 102 already described above, which are also applicable to the information processing system 202, are not described below to avoid duplicative description.

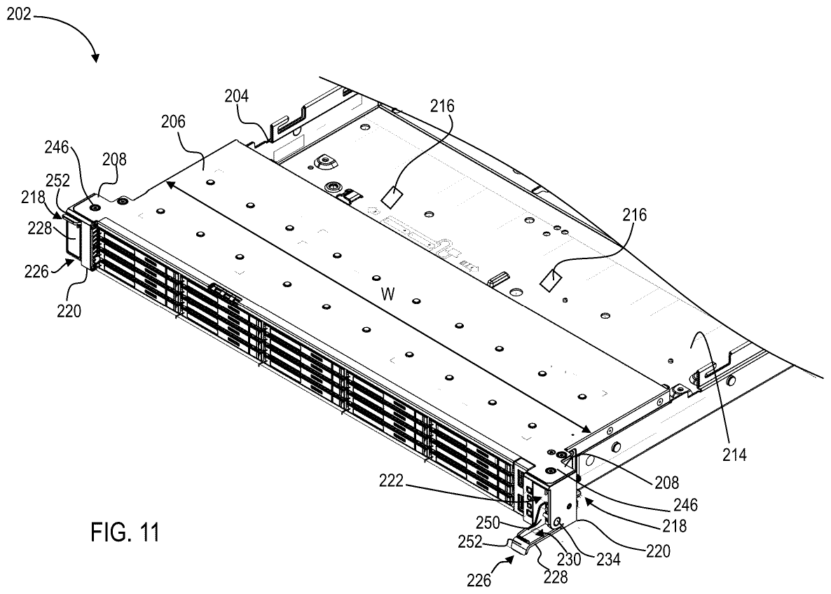

Information processing system 202 includes a chassis 204 and a set of the server ears 218, as shown in FIG. 11. Chassis 204 includes a top wall 206 and a base 210. Top wall 206 includes a set of top ear supports 208 disposed at each end of a width W of the top wall 206. Base 210 includes a set of bottom ear supports 212, as shown in FIG. 7, with bottom ear supports 212 disposed opposite top ear supports 208.

Each of the server ears 218 is one of the server ears 218 described above with respect to FIGS. 2-4. Each server ear 218 is coupled to the chassis 204 via one of the top ear supports 208 and via one of the bottom supports 212. While only one server ear 218 is fully visible in some figures, it should be understood that each server ear 218 has the same features. Each server ear 218 includes a server ear housing 220 having a pivot hole 224 formed within the server ear housing 220. The server ear housing 220 defines an interior receptacle, as shown in FIGS. 2-4.

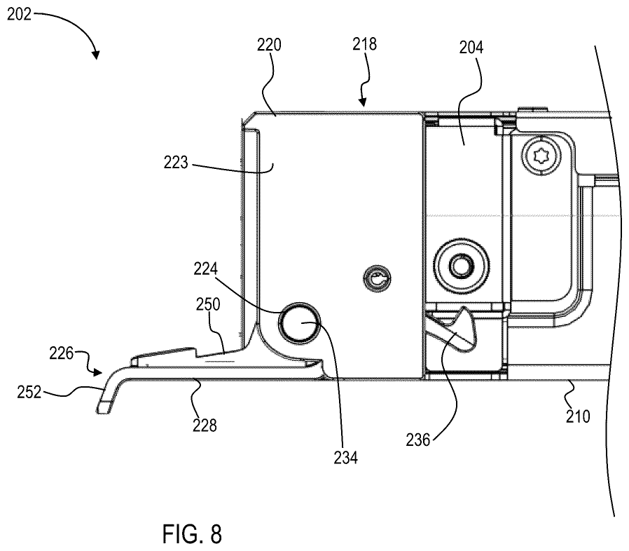

Server ear 218 further comprises a latch 236. As shown in FIGS. 7-8 in particular, a portion of latch 236 extends outwardly from server ear housing 220, opposite the lever 226. More particularly, as shown in FIG. 7, the latch 236 extends from the receptacle 222 formed in the server ear housing 220.

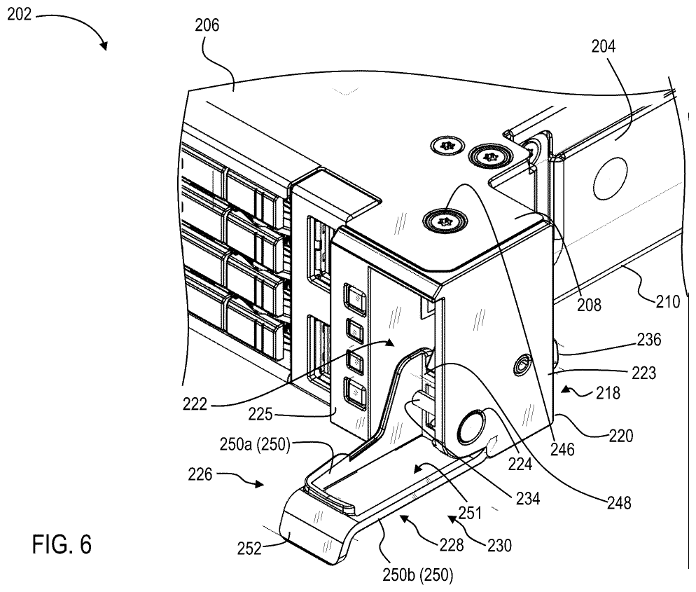

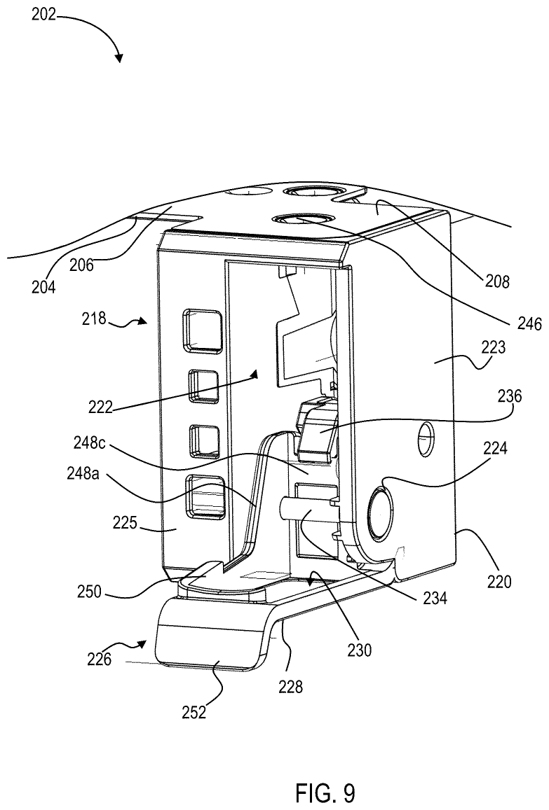

An opposite end of the latch 236 extends into receptacle 222 defined by server ear housing 220. As shown particularly with respect to FIG. 9, in the open state, the latch 236 engages with base 248 of lever 226. This engagement may take the form of a contact between the latch 236 and the base 248, engagement of complementary features on the latch 236 and the base 248, and the like. Such engagement between the latch 236 and the base 248, as shown in FIG. 9, allows the latch 236 to engage in maintaining the position and state of the lever 226. That is, latch 236 applies resistance to base 248 to aid in maintaining the lever handle 228 in a current state. In the open state shown in FIGS. 6-10, the resistance provided by latch 236 aids in preventing inadvertent rotation of lever 226, thus assisting in maintaining the accessibility of crane attachment point 230. By contrast, when lever 226 is in the closed state, the latch 236 aids in keeping the lever 226 in the closed state.

Latch 236 may include a biasing mechanism, such as biasing mechanism 139, shown in FIG. 1, which may aid the latch 236 in keeping the lever 226 in the open or closed state. In some examples, the biasing mechanism may include a spring, such as a torsion spring. For instance, the latch 236 may include a torsion spring internal to the latch 236, and when the lever 226 is in the closed state, the torsion spring may provide resistance (e.g., a biasing force) that aids in keeping the lever 226 in the closed state. In some examples, the biasing mechanism may additionally or alternatively include a pin, such as a cam actuated pin, which may be spring-loaded. As an illustrative example, the latch 236 may include a cam coupled to the latch 236 and arranged to acuate a pin such that the pin moves with latch 236 when the lever 226 is rotated. In some examples, the pin may engage with (e.g., apply a force at) the chassis 204 to maintain the lever 226 in the open state. The pin may further disengage from the chassis 204 (e.g., by reducing the force applied at the chassis 204) in the closed state via, for example, a spring force of a spring-loaded pin. In some examples, the pin may aid in biasing the latch 236 to keep the lever 226 in the closed state.

Application of a force to the lever 226 to move the lever 226 to the open position causes movement of the biasing mechanism such that the latch 236 is released and allows lever 226 to move. More particularly, the latch 236 is pivotably coupled to the side wall 223 of the server ear housing 220 such that when lever 226 moves, latch 236 is configured to pivot as well. Latch 236 is coupled to the side wall 223 via a latch hole 237, and more particularly via engagement of a pivot coupling, such as a pin extending through the latch hole 237 and through a corresponding feature on the latch 236. Thus, when lever 226 is moved about pivot pin 234, the biasing mechanism of latch 236 is also moved, allowing latch 236 to pivot about a connection with the server ear housing 220 at the latch hole 237.

Turning now to FIG. 11, chassis 204 includes a base (not labeled in FIG. 11) supporting a system board 214. The system board includes electronic components 216. Although two electronic components 216 are shown, examples are not so limited and more or fewer electronic components may be disposed on the system board 214. Chassis 204 further includes a top wall 206. As shown in FIG. 11, top wall 206 is a partial top wall, extending over only a portion of system board 214. However, examples are not so limited and top wall 206 may extend so as to fully cover system board 214. Top wall 206 includes two top ear supports 208 separated by width W such that the top ear supports 208 are disposed at opposite ends of top wall 206. As shown in FIG. 11, top ear supports 208 extend outwardly from the top wall 206 to allow server ears 218 to be coupled to the chassis 204 at the top ear supports 208. Chassis 204 further comprises bottom ear supports (not shown in FIG. 11) that are part of the base.

System 202 further comprises a set of server ears 218. As shown in FIG. 11, one server ear 218 is shown in a closed state while a second server ear 218 is shown in an open state; however, it should be understood that each server ear 218 has the same components. Each server ear 218 comprises a server ear housing 220, a lever 226, and a latch (shown and discussed with respect to FIGS. 6-10).

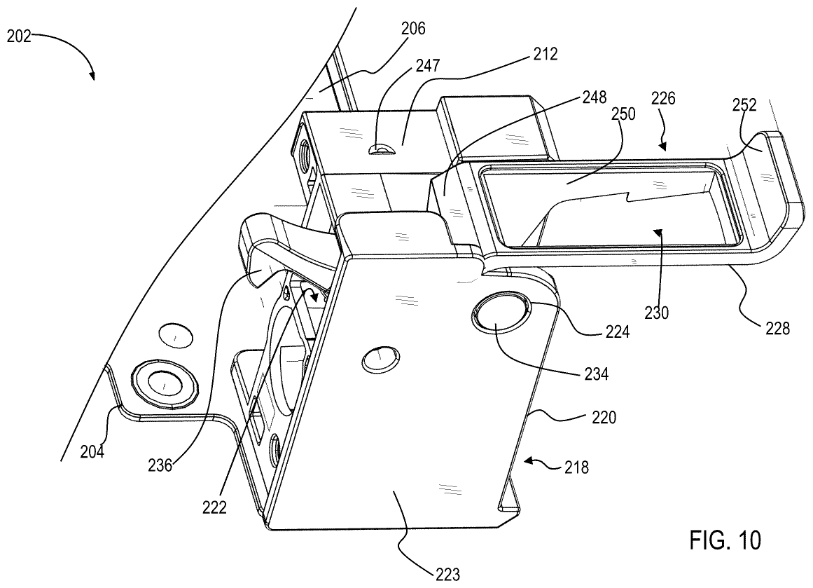

Server ear 218 is coupled to chassis 204 and more particularly to top ear support 208 via at least one fastener 246 between the top ear support 208 and the server ear housing 220. A similar fastening is used to couple server ear housing 220 to the bottom ear support, as shown in FIG. 10. Although only one fastener 246 is shown with each server ear 218, more fasteners 246 may be used for one or both of the set of server ears 218. In addition, while fasteners 246 are shown coupling server ear 218 to chassis 204, examples are not so limited and other types of mechanisms may be used to engage the server ear 218 and the chassis 204. For example, a cam actuated pin may be coupled to the latch 236 such that the pin moves with latch 236 when the lever 226 is rotated to allow the pin to engage with the chassis 204 at the top ear support 208.

Server ear housing 220 defines a receptacle 222, with receptacle 222 extending at least partially through server ear housing 220. A lever 226, and particularly a lever handle 228, is configured to be pivotably coupled to the server ear housing 220 via a pivot pin 234 such that a crane attachment point 230 defined in the lever handle 228 is configured to be received in the receptacle 222 when the lever 226 is in the closed state.

Lever handle 228 comprises a set of arms 250, a grasping tab 252 coupled to the set of arms 250, and a base coupled to the set of arms 250 opposite the grasping tab 252. In FIG. 8, the base is within the receptacle 222; however, the base is shown and discussed with respect to FIGS. 6-10. In addition, while one arm 250 is shown as part of the lever handle 228 in the open state of the lever 226, it should be understood that a second arm is disposed opposite the arm 250. Crane attachment point 230 is an opening through lever handle 228 bounded by the grasping tab 252, the side arms 250, and the base. In the open state, crane attachment point 230 is accessible for engagement with an attachment device on an overhead crane, whereas in the closed state, crane attachment point 230 is received within receptacle 222 and is thus inaccessible to the attachment device of the overhead crane.

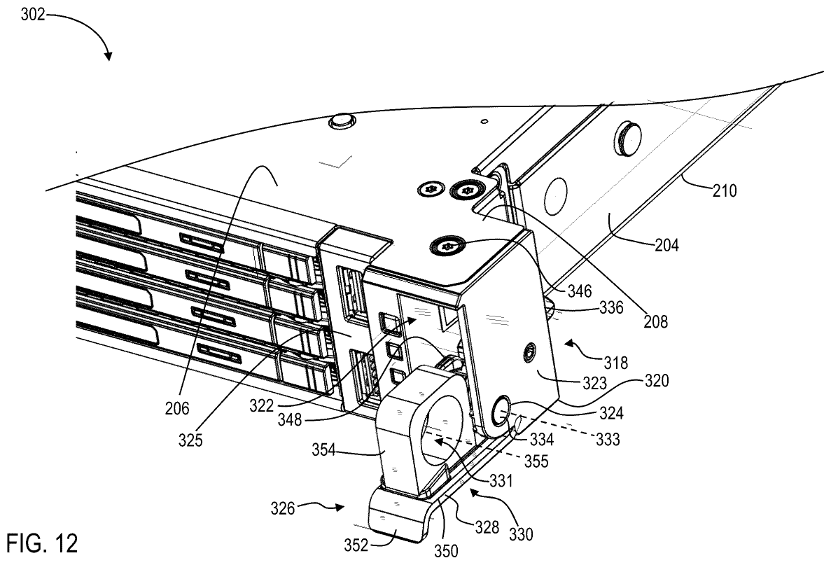

Turning to FIGS. 12-14, an example information processing system 302 including a server ear 318 will be described. Server ear 318 may be one implementation of an example server ear 118, shown in and described with respect to FIG. 1, and may be used in a system such as system 100, described with respect to FIG. 1. Some aspects of server ear 318 are best visible in figures also showing system 302, and thus server ear 318 and system 302 will be described together below, but it should be understood that server ear 318 could be used in other systems. Server ear 318 thus comprises components which correspond to (i.e., are implementation examples of) components of the server ear 118, and the correspondence between such components is indicated herein by the components having references numbers with the same last two digits, such as 120 and 320. Aspects of the server ear 118 and its components described above may also be applicable to the server ear 318 and its corresponding components, but the server ear 118 and its components are not limited to the server ear 318 and its components, which are just one example of how the server ear 118 may be implemented. In some instances, aspects of the server ear 118 already described above, which are also applicable to the server ear 318, are not described below to avoid duplicative description.

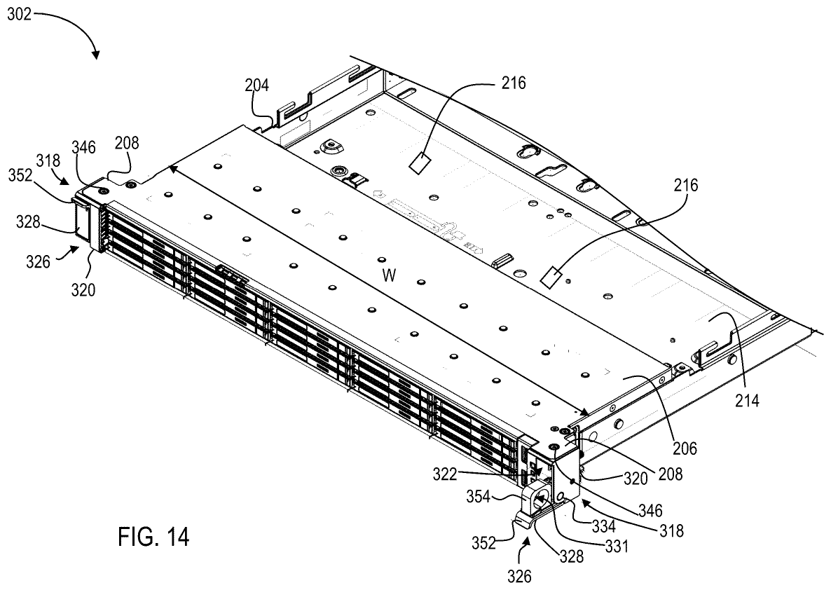

Information processing system 302 includes a chassis 204, which may be the same chassis 204 described with respect to FIGS. 5-11, and a server ear 318. The chassis 204 includes a top wall 206 and a base 210. The base 210 supports a system board 214. The system board includes electronic components 216. Although two electronic components 216 are shown, examples are not so limited and more or fewer electronic components may be disposed on the system board 214. Chassis 204 further includes a top wall 206. As shown in FIG. 14, top wall 206 is a partial top wall, extending over only a portion of system board 214; however, examples are not so limited and top wall 206 may extend so as to fully cover system board 214.

The top wall 206 of the chassis 204 includes two top ear supports 208 separated by width W such that the top ear supports 208 are disposed at opposite ends of top wall 206 and extend outwardly from the top wall 206 to allow server ears 318 to be coupled to the chassis 204 at the top ear supports 208. Chassis 204 further comprises bottom ear supports that are part of the base 210, with the bottom ear supports being disposed opposite the top ear supports 208.

System ear 318 includes a system ear housing 320, a lever 326, and a bracket 354 coupled to lever 326.

The server ear 318 is coupled to the chassis 204, and more particularly to the top ear support 208, by at least one fastener 346. Fastener 346 may be a screw, pin, welding, or any other fastener. While one fastener 346 is shown in FIG. 12, it should be understood that more fasteners may be included to couple server ear 318 to top ear support 208.

A receptacle 322 is defined by system ear housing 320, with receptacle 322 extending at least partially through the system ear housing 320. Receptacle 322 is configured to receive bracket 354 when lever 326 is in a closed state, as described further herein. System ear housing 320 further comprises at least one pivot hole 324 extending through system ear housing 320.

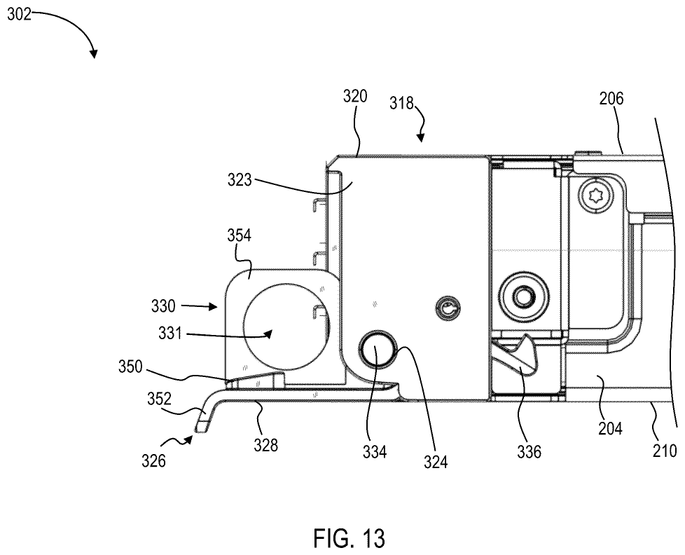

Lever 326 comprises a lever handle 328 and a base 348 pivotably coupled to the system ear housing 320. More particularly, lever 326 includes a pivot hole configured to align with pivot hole 324 such that a pivot pin 334 can be passed through the server ear housing 320 and the lever 326 to allow lever 326 to pivot with respect to the server ear housing 320 between an open state, shown in FIGS. 12-13, and a closed state.

Lever handle 328 comprises an arm 350 coupled to base 348 and a grasping tab 352 coupled to distal end of arm 350 opposite the base 348. The grasping tab 352 is coupled to the arm 350 and extends from the arm 350 opposite the base. As shown in FIGS. 12-13, when lever 326 is in an open state, grasping tab 352 is separated from server ear housing 320.

In this example, the lever handle 328 includes a bracket 354 coupled to the arm 350 such that bracket 354 protrudes from the arm 350 in a direction perpendicular to a direction of extent of the arm 350. In some examples, the bracket 354 is integrally formed with the arm 350. In other examples, the bracket 354 is attached to the arm 350 by fasteners, welding, or other fastening/joining techniques. The bracket 354 includes an opening 331 defined through the bracket 354, with the opening 331 and the surrounding portions of the bracket 354 together forming a crane attachment point 330. The crane attachment point 330 is configured to receive a crane attachment device, such as a hook, when lever 326 is in an open state. That is, a crane attachment device may be attached to information processing system at crane attachment point 330 when the lever 326 is open. Bracket 354 is oriented such that the opening 331 has an axis 355 that is parallel to an axis of rotation or pivot axis 333 of the lever 326 with respect to the server ear housing 320. As a result, the crane attachment point 330 allows a crane attachment device to be coupled to the information processing system parallel to the rotational axis of the lever 326.

Bracket 354 is configured to be received within receptacle 322 when lever 326 is pivoted about axis 333 from the open state, shown in FIGS. 12-13, to a closed state. In the closed state, when bracket 354 is held within receptacle 322, crane attachment point 330 is also within receptacle 322 such that it is not accessible for attachment to a crane attachment device.

Server ear 318 further comprises a latch 336. As shown in FIG. 13 in particular, a portion of latch 336 extends outwardly from server ear housing 320, opposite the lever 326. More particularly, as can be seen in FIG. 12, the latch 336 extends from the receptacle 322 formed in the server ear housing 320. When the lever 326 is in the open state, as shown in FIG. 13, an end of the latch 336 extends into receptacle 322 defined by server ear housing 320. As shown particularly with respect to FIG. 12, in the open state, the latch 336 contacts base 348 of lever 326 to engage the lever 326 at the base 348. to aid in maintaining the position and state of the lever 326 by applying resistance to base 348. In the open state shown in FIGS. 12-13, the resistance provided by latch 336 aids in preventing inadvertent rotation of lever 326, thus assisting in maintaining the accessibility of crane attachment point 330.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a system board comprising electronic components;
a chassis supporting the system board, the chassis comprising:
a top wall having a top ear support; and
a base having a bottom ear support; and
a server ear comprising:
a server ear housing coupled to the chassis at the top ear support and the bottom ear support; and
a lever, comprising:
a base pivotably coupled to the server ear housing; and
a lever handle extending from the base and comprising a crane attachment point configured to engage a crane attachment device of a crane of an immersion cooling system to attach the information processing system to the crane such that the information processing system is liftable by the crane with the server ear supporting the information processing system;
wherein the lever handle is configured to be movable between an open state in which the crane attachment point is accessible for engagement with the crane attachment device and a closed state in which the crane attachment point is inaccessible for engagement with the crane attachment device.

2. The information processing system of claim 1, wherein:
the crane attachment device is a crane hook; and
the crane attachment point comprises an opening through the lever handle configured to receive the crane hook.

3. The information processing system of claim 2, wherein the opening through the lever handle has an axis parallel to a pivot axis of the lever.

4. The information processing system of claim 3, wherein the lever handle comprises:
a set of arms coupled to the base; and
a grasping tab coupled to the set of arms opposite the base, wherein the opening is defined between the set of arms, the grasping tab, and the base.

5. The information processing system of claim 1, wherein the lever handle comprises:
an arm coupled to and extending from the base;
a grasping tab coupled to the arm opposite the base; and
a bracket coupled to and protruding from the arm, wherein the opening is formed through the bracket.

6. The information processing system of claim 5, wherein the opening through the bracket has an axis perpendicular to a pivot axis of the lever.

7. The information processing system of claim 1, wherein:
the server ear housing defines a receptacle; and
the crane attachment point is housed in the receptacle when the lever handle is in the closed state.

8. The information processing system of claim 1, further comprising a latch pivotably coupled to the server ear housing, wherein the latch is configured to engage with the base of the lever to apply resistance to aid in maintaining the lever handle in the open state or in the closed state.

9. The information processing system of claim 1, wherein:
the server ear housing includes at least one server ear housing pivot hole;
the lever includes at least one lever pivot hole; and
the lever is pivotably coupled to the server ear housing via engagement of a pivot pin between the at least one server ear housing pivot hole and the at least one lever pivot hole.

10. An immersion cooling system, comprising:
an immersion tank having liquid coolant held therein; and
the information processing system of claim 1 configured to be selectively immersed within the liquid coolant in the immersion tank.

11. A method of preparing a server for lifting by a crane of an immersion cooling system comprising:
coupling a server ear housing with a chassis of an information processing system, the server ear housing comprising a receptacle; and
pivotably coupling a base of a lever to the server ear housing, the lever comprising a lever handle extending from the base and including a crane attachment point configured to engage a crane attachment device of a crane of the immersion cooling system to attach the information processing system to the crane such that the information processing system is liftable by the crane with the server ear supporting the information processing system;
wherein the lever handle is configured to be movable between a closed state and an open state.

12. The method of claim 11, further comprising pivotably coupling a latch to the server ear housing, wherein:
the latch is configured to selectively engage with the chassis and with the base of the lever; and
the latch is configured to pivot when the lever handle is moved between the closed state and the open state.

13. The method of claim 11, wherein coupling a server ear housing with the chassis further comprises:
coupling a top wall of the server ear housing to a top ear support of the chassis via at least one screw configured to pass through an opening in the top ear support and an aperture in the top wall of the server ear; and
coupling a bottom wall of the server ear housing to a bottom ear support of the chassis via at least one screw configured to pass through an opening in the bottom ear support and an aperture in the bottom wall of the server ear.

14. The method of claim 11, wherein rotatably coupling a base of a lever to the server ear housing comprises:
aligning at least one pivot hole in the server ear housing with at least one pivot hole in an arm of a pair of arms of the lever, wherein the pair of arms are coupled to the base; and
passing a pivot pin through the at least one pivot hole in the server ear housing and the at least one pivot hole in the lever.

15. The method of claim 11, wherein:
in the closed state, the crane attachment point is received within the receptacle of the server ear housing; and
in the open state, the crane attachment point is accessible for engagement with the crane attachment device.

16. A server ear configured for installation in an information processing system, comprising:
a server ear housing, comprising:
a top wall;
a bottom wall disposed opposite the top wall; and
a set of side walls disposed between and connecting the top wall and the bottom wall; and
a receptacle defined by the top wall, the bottom wall, and the set of side walls; and
a lever, comprising:
a lever handle, the lever handle comprising:
a set of arms comprising a crane attachment point configured to engage a crane attachment device of a crane of an immersion cooling system; and
a grasping tab coupled to the set of arms; and
a base coupled to the lever handle at the set of arms.

17. The server ear of claim 16, wherein the server ear further comprises a rear wall coupled to the top wall, the bottom wall, and the pair of side walls.

18. The server ear of claim 16, wherein:
each side wall of the set of side walls further comprises a side wall pivot hole formed through the side wall; and
each arm of the set of arms further comprises a lever pivot hole formed through the arm.

19. The server ear of claim 18, wherein the lever is configured to couple to the server ear housing by alignment of the side wall pivot holes with the lever pivot holes to allow a pivot pin to pass through the side wall pivot holes and the lever pivot holes.

20. The server ear of claim 16, wherein the crane attachment point comprises a bracket configured to extend outwardly from the lever handle.
